(19) United States
(12) Patent Application Publication
(10) Pub. No.: US 2010/0237325 A1
(43) Pub. Date: Sep. 23, 2010

(54) Highly resolved, low noise, room-temperature coulomb-staircase and blockade up to 2.2V in isolated 50 micron long one dimensional necklace of 10 NM AU particles

(75) Inventors: Ravi F. Saraf, Lincoln, NE (US); Vikas Berry, Lincoln, NE (US); Sanjun Niu, Lincoln, NE (US)

Correspondence Address: FISH & RICHARDSON P.C., PO BOX 1022, MINNEAPOLIS, MN, 55440-1022, US

(73) Assignee: BOARD OF REGENTS OF UNIVERSITY OF NEBRASKA, LINCOLN, NE (US)

(21) Appl. No.: 11/477,263

(22) Filed: Jun. 29, 2006

Related U.S. Application Data
(60) Provisional application No. 60/694,852, filed on Jun. 29, 2005.

(51) Int. Cl. H01L 39/22; B05D 5/12; H01L 21/283

(52) U.S. Cl. 257/30; 427/58; 438/686; 257/E21.159; 257/E39.013; 977/932

(57) ABSTRACT

Coulomb blockade in metal nanoparticles isolated by a tunneling barrier is considered to be a potential solution to low power, robust, high-speed electronic switching device operating at single-electron transport. However, the switching voltage equal to the threshold voltage to overcome coulomb blockade for these devices is typically in the 10 mV range and/or operating at currents well below 1 nA, which inhibits their application as a practical device. Theoretically, a one dimensional nanoparticle necklace is predicted to be an ideal structure to achieve higher switching voltages. The present invention provides a single-electron device composed of a necklace of about 5000 nanoparticles. The linear necklace is self-assembled by interfacial phenomena along a triple-phase line of fiber, a substrate and electrolyte containing nanoparticles. The I-V measurements on the system show both coulomb blockade and staircase, with high currents and high threshold voltage of 1-3 V. The present invention also provides methods for constructing such a device.

### CROSS-REFERENCE TO RELATED APPLICATIONS

This application claims the benefit of U.S. Provisional Application Ser. No. 60/694,852, filed Jun. 29, 2005 and entitled “Highly Resolved, Low Noise, Room-Temperature Coulomb-Staircase and Blockade up to 2.2V in Isolated 50 Micron Long One Dimensional Necklace of 10 NM AU Particles,” which is hereby incorporated herein by reference.

### STATEMENT REGARDING FEDERALLY SPONSORED RESEARCH OR DEVELOPMENT

None.

### BACKGROUND OF THE INVENTION

As electronics technology shrinks, the performance of devices based on conventional semiconductors will become more challenging due to fundamental physical limits and more complex and expensive lithography processes. For example, statistical fluctuation in dopant concentration will add significant variability in the threshold voltage (i.e., gate voltage for drain current switched on) among devices on the chip as the channel width shrinks well beyond 100 nm; higher electric fields due to smaller distances can lead to avalanche (breakdown) of electrons causing progressive damage to the device; and the concomitant shrinkage of characteristics features (i.e., gate oxide and depletion layer thickness) could lead to current leakage due to quantum mechanical electron tunneling effect. Devices based on alternative physical phenomena to attain electronic switching without dopant and low (preferably single) electron transport are of great interest. It has been long known over two decades that nanoscale metal island isolated by dielectric barrier is an attractive solution to fabricate switching device for logic and memory where the charge transport is regulated at single-electron level. The single-electron tunneling (SET) junction occurs due to low capacitance of the island to store charge causing a Coulomb blockade against the next electron insertion into the nanoscale island. The result is a highly non-linear current (I)-voltage (V) characteristics where the current abruptly increase over a threshold bias, V_{CB} that overcomes the required Coulomb blockade energy. However, the blockade energy, U=0.5EV_{CB} (approximately 1 meV for 100 nm island) is very low requiring operation below 10K to avoid thermal fluctuations.

Recently, by replacing the lithographically patterned metal island with (usually Au) nanoparticle having diameter of approximately 3-10 nm, the threshold energy can be raised approximately 100 meV making it possible to obtain Coulomb blockade at room temperature. SET devices operating at room and low temperatures, such as transistors and negative-differential-resistance using single nanoparticle have been demonstrated. However, for a viable single-electron digital device the charging energy must be approximately 100 kT to avoid thermally induced random tunneling. Thus, for a practical SET device operating at room temperature, V_{CB} must be approximately 2.5V, a 25-fold increase from currently achieved nanoparticle based devices. Extending the above idea to particles <1 nm, V_{CB}>5 V has been demonstrated in one recent study. However, for d<1 nm, the blockade characteristics are significantly smeared due to high sensitivity to size variations (approximately d³) caused by energy quantization effects; the operating currents drop by 10³ fold in <1 pA as particle size decreases from about 1.8 nm to 0.7 nm, and charge fluctuations lead to significant drift in the I-V characteristic features over time. Based on theoretical calculations, a one dimensional necklace of larger nanoparticles could be an ideal structure to achieve higher switching voltages, with higher currents.

### BRIEF SUMMARY OF THE INVENTION

The present invention provides a highly resolved, low noise, room temperature Coulomb-staircase and blockade and methods for constructing a Coulomb-staircase and blockade in accordance with the present invention. The present invention may utilize a substrate with at least one pair of electrodes. Fibers, such as polystyrene fibers, may be spun out of a solution on the substrate such that a fiber extends across the pair of electrodes. The substrate and fibers may then be immersed in a solution containing suspended nanoparticles that adhere to the fibers, thereby forming a one dimensional necklace of nanoparticles between the electrodes.

### BRIEF DESCRIPTION OF THE SEVERAL VIEWS OF THE DRAWING

FIG. 1 illustrates a nanoparticle necklace in accordance with the present invention schematically;

FIG. 2 illustrates a method for constructing a nanoparticle necklace in accordance with the present invention;

FIG. 3 illustrates the electrical properties of a nanoparticle necklace in accordance with the present invention; and

FIG. 4 further illustrates the electrical properties of a nanoparticle necklace in accordance with the present invention.

### DETAILED DESCRIPTION OF THE INVENTION

The present invention provides a general approach to achieve a large enhancement in V_{CB} by self-assembling a near perfect one-dimensional (1-D) “necklace of nanoparticles.” An exemplary embodiment described herein uses approximately 5000 Au particles of diameter of approximately 10 nm. In this exemplary embodiment, sites in the necklace are isolated “islands” with SET characteristics that lead to an extremely high, robust and reproducible V_{CB} of about 2.2 V. The self-assembly is a simple process where the nanoparticles agglomerate at an edge of a polymer fiber to produce a 1-D percolating channel. A simple model based on a composite structure of “ohmic channels” and single nanoparticle “islands” explains the large V_{CB} behavior. For longer deposition time, there is an annealing effect such that the currents jump by approximately 5-fold and a sharp Coulomb staircase behavior is observed. The charging energy is same as the pure blockade behavior corresponding to V_{CB} of approximately 2.2V and the nanoparticle (island) resistance is consistent with reported single-nanoparticle SET devices operating at room temperature.

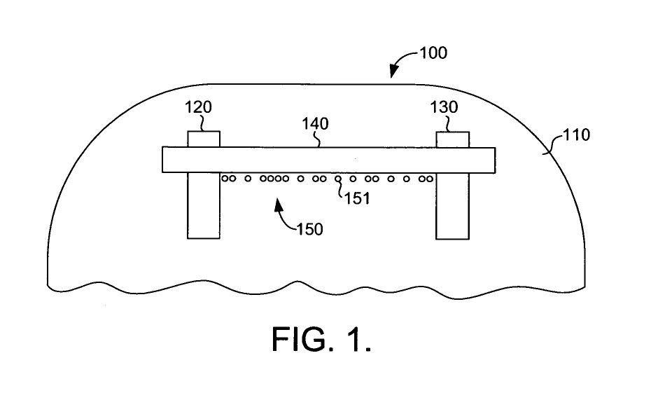

FIG. 1 illustrates an example of a nanoparticle necklace 100 in accordance with the present invention. FIG. 1 is not to scale. A substrate 110 may be comprised of a layer of SiO₂ over a Si wafer. A pair of electrodes 120, 130 may comprise a set of 1 mm wide Au electrodes spaced at 50 μm apart on substrate 110, although other types and sizes of electrodes may be used. Fiber 140 may comprise a polystyrene fiber extending across the pair of electrodes 120, 130, although other types of fibers may be used. A plurality 150 of nanoparticles, such as nanoparticle 151, are adhered to fiber 140 between first electrode 120 and second electrode 130. While plurality 150 of nanoparticles may be selected to possess any type of electrical and/or chemical properties desired, in the exemplary embodiment nanoparticles of Au having a diameter of approximately 10 nm are used.

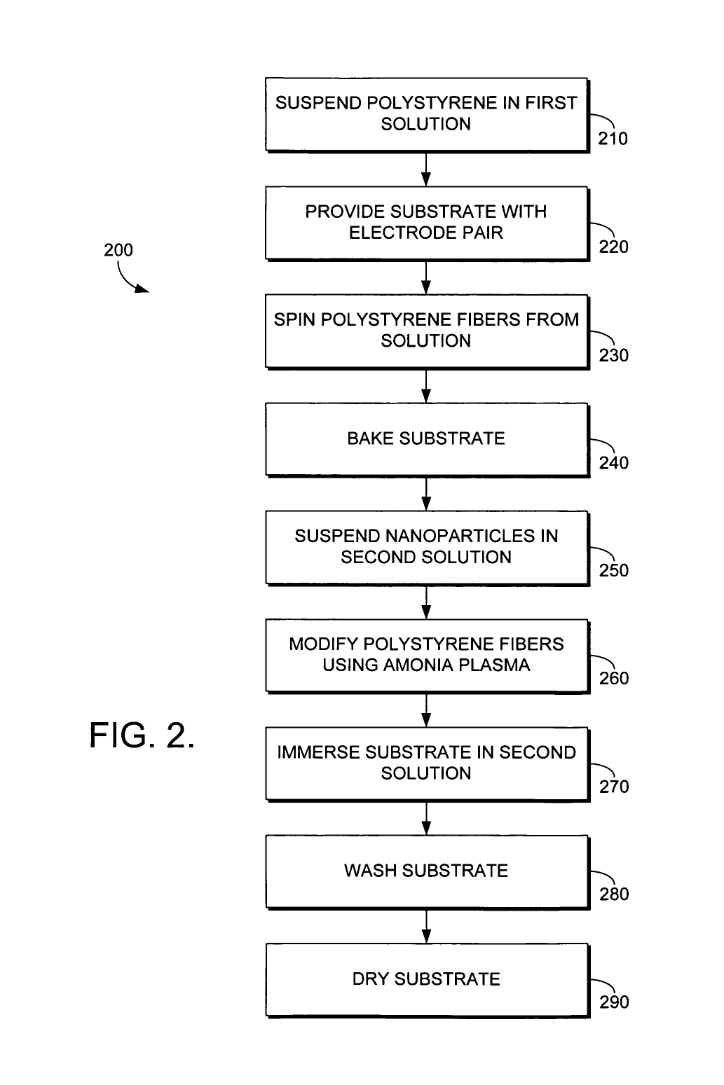

FIG. 2 illustrates a method 200 for fabricating a necklace of nanoparticles in accordance with the present invention. In step 210 fiber material, such as polystyrene, may be suspended in a first solution. In step 220 a substrate, such as described above with regard to FIG. 1, having an electrode pair may be provided. In step 230 the fibers may be spun from the solution. For example, polystyrene fibers may be spun on a substrate using spindle rotating at approximately 5000 rpm from an approximately 15% solution in toluene. The diameter of the fibers may be approximately 600 nm. The fibers may cross a set of 1 mm wide Au electrodes spaced at 50 μm on the substrate. The substrate and fibers may be subsequently baked in vacuum of approximately 1 mtorr at approximately 120° C. for about 20 minutes to flatten the fibers at the fiber/substrate interface. In step 250 nanoparticles may be suspended in a second solution. The suspended nanoparticles may be negatively charged 10 nm Au particles. The second solution in which the nanoparticles are suspended may be an aqueous solution at pH of approximately 4. In step 260 the polystyrene fiber surface may be modified with an amine group by exposure to ammonia plasma for approximately 20 seconds. After step 260 method may immediately proceed to step 270, in which the substrate and fibers may be immersed in the second solution containing suspended nanoparticle. The immersion of step 270 may last for approximately 8 hours. In step 280 the substrate and structures on the substrate may be washed thoroughly with water. In step 290 the substrate and structures on the substrate may be air-dried. One skilled in the art will appreciate that the temperatures, pressures, pHs, time periods, solution types, and material types described above are approximate only, and may be varied without departing from the scope of the present invention.

FIG. 2 illustrates the electrical properties of a nanoparticle necklace in accordance with the present invention. Typical characteristics of a nanoparticle necklace in accordance with the present invention include: (i) a highly well defined V_{CB} at about 2.2 V; (ii) the I-V is robust over several I-V cycles spanning multiple days; (iii) virtually no hysteresis is observed; (iv) the behavior after the threshold voltage is linear, indicating transport in a 1-D necklace; (v) most significant are the switching characteristics: over an excursion of 1.7 to 2.7 V the current changes by 6.5 fold (from 2 V to 6 V it changes 31 fold, from 1 to 2V the increase is 2 fold, while from 2 to 3 V, the increase is 9 fold); and (vi) the operating current is high, in 10¹ nA range.

The capacitance of a nanoparticle of diameter d, surrounded by organic tunneling barrier of dielectric constant, ∈, is cₙₚ=2π∈∈₀d, where ∈₀ is the permittivity in vacuum. Therefore, for a single nanoparticle device of d=10 nm, the energy to charge the particle with a second electron is, U=e2/(21 tssod)˜0.065 eV corresponding to about 3 kT at room temperature. Thus, the passage of electron above a threshold bias of V_{CB} of about 0.065 V will not be blocked by Coulomb repulsion. The 50 fold increase in the V_{CB} compared to single 10 nm particle measurements is explained as follows.

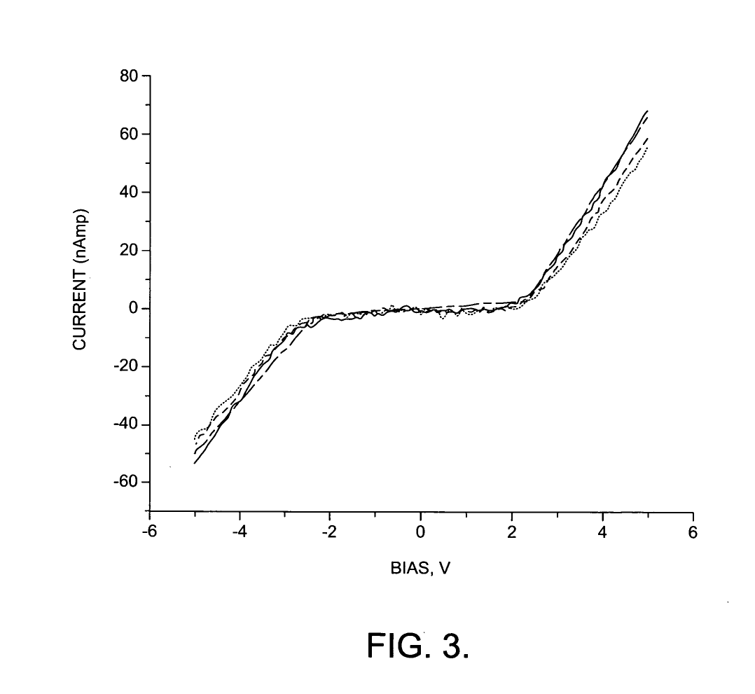

Referring again to FIG. 1, the nanoparticle necklace may be thought of as being composed of “clusters” with identical single nanoparticle “islands” marked. The “clusters” are closely packed nanoparticles, perhaps aided by some adjacent rows of nanoparticles, where the tunneling resistance is low resulting in a close to Ohmic behavior similar to high density monolayer of nanoparticles. The islands are a single nanoparticle spaced by a larger gap leading to SET characteristics. For bias below V_{CB}, the necklace can be assumed to be a pure capacitor with a capacitance, cₜ=cₙₚ/n , where n is the number of islands, and cₙₚ is the individual capacitance of the nanoparticle residing in the island. At V_{CB} corresponding to charging each of the islands with a single electron charge, e, is given by ne/cₜ or n²e/cₙₚ. Thus, the V_{CB} corresponding to single nanoparticle is amplified by n² in the 1-D necklace. For bias above V_{CB}, the current rises linearly following Ohms law with an effective resistance of Rₜ=n (Rₙₚ+R_{c}), where R_{c} and Rₙₚ are cluster and the nanoparticle island resistances, respectively. At a total bias, V, between the electrodes leading to current I, the resistive drop across the island nanoparticle, Rₙₚ is given by, f(V−V_{CB})/n=IRₙₚ, where f=Rₙₚ/(Rₙₚ+R_{c}). Thus the I-V characteristics for V>V_{CB} becomes, V=V_{CB}+IRₜ which is consistent with observations in FIG. 3. This equation is similar to I a [V/V_{CB}−1]^{ζ}, where ζ=1 for 1-D arrays. Assuming, an ∈˜3 (reasonable for organic surrounding), cₙₚ˜2.5×10⁻¹⁸ F. For a measured V_{CB} of 2.2V, the number of SET islands n=(cₙₚV_{CB}/e)^{0.5} are about 6. Within 10%, it is reasonable to neglect R_{c} relative to Rₙₚ, i.e., f approximately 1. Based on the measured Rₜ of approximately 42.2 MΩ, the estimated value of SET resistance, Rₙₚ≈Rₜ/n ˜7 MΩ, which is reasonable compared to the reported values.

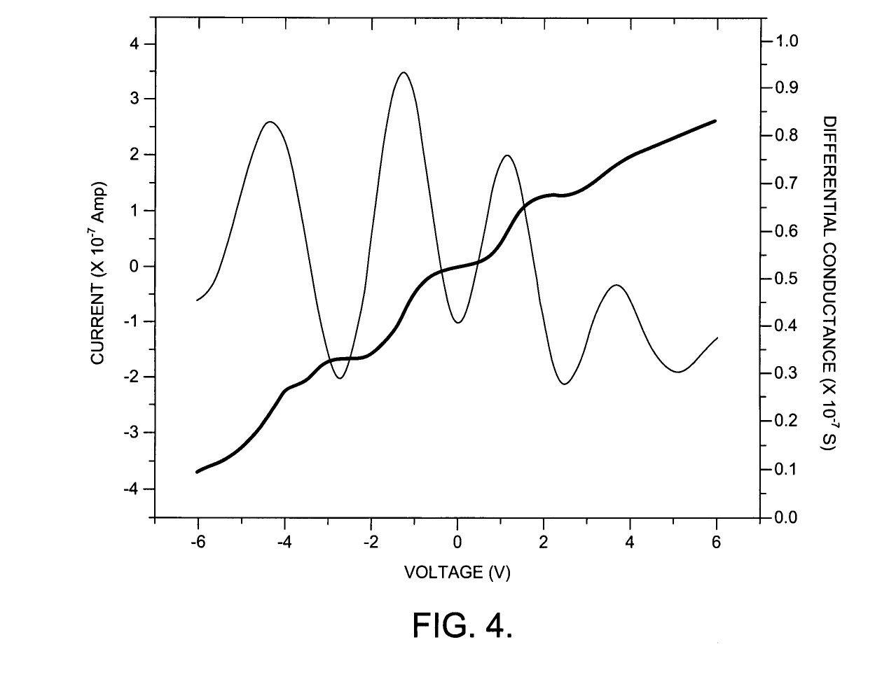

FIG. 4 shows an I-V of Au nanoparticle for 12 hour deposition exhibiting a Coulomb staircase effect. The periodic modulation of the differential conductance is about 2.2 V, indicating that the charging energy is identical to the Coulomb staircase, i.e., n ˜6. The I-V characteristics are similar to previously reported Coulomb staircases in single nanoparticle at room temperature, however the currents are 1 to 3 orders of magnitude larger and most importantly the switching voltage, V_{CB} is increased form <0.1 V to 2.2V (i.e., charging energy is about 100 kT). Interestingly, contrary to theoretical models that predict the coulomb staircase cannot be obtained in isolated 1-D system due to significant smearing effects, a sharp staircase indicating high coherence in charge transport among the islands was observed.

The present invention provides an approach to assemble a necklace of nanoparticles along an edge of a dielectric to fabricate a switching device that exhibits Coulomb staircase and blockade effects at room temperature. Importantly, the switching voltage, V_{CB}˜n² can be tailored by controlling the number of “isolated islands” in the necklace during the fabrication process. The following three features open the possibility of self assembling practical nanodevices based on coulomb blockade effect: (i) the I-V characteristics are robust (i.e., high reproducibility, large operating currents, and sharp blockade effect); (ii) V_{CB} is close to about 100 kT at room temperature; and (iii) in principle the edge may be produced by patterning dielectric by lithographic techniques. It's envisioned that, with clever surface modification of edge and lithographic methods of patterning the edges, complex networks of nanoparticle necklaces can be fabricated to obtain robust digital devices operating at room temperature.

What is claimed is:

1. A method for fabricating a necklace of nanoparticles, the method comprising:
suspending fiber materials in a first solution;
spinning the fibers from the solution on a substrate;
suspending nanoparticles in a second solution; and
immersing the substrate and fibers in the second solution containing the suspended nanoparticles, such that the suspended nanoparticles may adhere to the fibers.

2. The method for fabricating a necklace of nanoparticles of claim 1, further comprising:
baking the substrate and fibers after spinning the fibers from the solution on the substrate.

3. The method for fabricating a necklace of nanoparticles of claim 1, further comprising:
washing the substrate after immersing the substrate in the second solution containing the suspended nanoparticles; and
drying the substrate with the fibers and nanoparticles.

4. The method for fabricating a necklace of nanoparticles of claim 2, further comprising:
washing the substrate after immersing the substrate in the second solution containing the suspended nanoparticles; and
drying the substrate with the fibers and nanoparticles.

5. A method for fabricating a necklace of conducting nanoparticles on a substrate, the method comprising:
suspending fiber materials in a first solution;
providing a substrate with a pair of electrodes;
spinning the fibers from the solution on the substrate such that a fiber crosses both of the pair of electrodes;
baking the substrate and fibers to flatten the fibers;
suspending conducting nanoparticles in a second solution;
immersing the substrate and fibers in the second solution containing the suspended conducting nanoparticles; such that the suspended conducting nanoparticles may adhere to the fibers; washing the substrate, fibers, and conducting nanoparticles; and
drying the substrate, fibers, and nanoparticles.

6. The method for fabricating a necklace of conducting nanoparticles on a substrate of claim 5, wherein:
the fibers comprise polystyrene fibers.

7. The method for fabricating a necklace of conducting nanoparticles on a substrate of claim 6, further comprising:
modifying the surface of the polystyrene fibers by exposure to ammonia plasma prior to immersing the substrate and fibers in the second solution containing the suspended conducting nanoparticles.

8. The method for fabricating a necklace of conducting nanoparticles on a substrate of claim 7, wherein:
the conducting nanoparticles comprise negatively charged.

9. The method for fabricating a necklace of conducting nanoparticles on a substrate of claim 7, wherein:
the conducting nanoparticles comprise negatively charged Au particles.

10. The method for fabricating a necklace of conducting nanoparticles on a substrate of claim 9, wherein:
the negatively charged Au nanoparticles have a diameter of approximately 10 nm.

11. The method for fabricating a necklace of conducting nanoparticles on a substrate of claim 10, wherein:
the substrate comprises a SiO₂ layer over a Si wafer.

12. The method for fabricating a necklace of conducting nanoparticles on a substrate of claim 11, wherein:
the pair of electrodes comprise Au electrodes spaced approximately 50 μm apart.

13. The method for fabricating a necklace of conducting nanoparticles on a substrate of claim 12, wherein:
baking the substrate and fibers further comprises baking in a vacuum of approximately 1 mtorr.

14. The method for fabricating a necklace of conducting nanoparticles on a substrate of claim 13, wherein:
the first solution comprises toluene.

15. The method for fabricating a necklace of conducting nanoparticles on a substrate of claim 13, wherein:
the second solution comprises an aqueous solution at a pH of approximately 4.

16. The method for fabricating a necklace of conducting nanoparticles on a substrate of claim 15, wherein:
immersing the substrate and fibers in the second solution containing the suspended conducting nanoparticles comprises immersing the substrate and fibers in the second solution for approximately 8 hours.

17. A necklace of conducting nanoparticles comprising:
a substrate comprising a layer of SiO₂ over a wafer of Si;
a pair of electrodes approximately 50 μm apart on the substrate;
a polystyrene fiber extended between the pair of electrodes; and
at least one conducting nanoparticle adhered to the polystyrene fiber between the pair of electrodes.

18. The necklace of conducting nanoparticles of claim 17, wherein:
the at least one conducting nanoparticle comprises at least one Au nanoparticle.

19. The necklace of conducting nanoparticles of claim 18, wherein:
the at least one Au nanoparticle has a diameter of approximately 10 nm.

20. The necklace of conducting nanoparticles of claim 19, wherein:
the at least one Au nanoparticle having a diameter of approximately 10 nm comprises a plurality of Au nanoparticles having diameter of approximately 10 nm.
